(19) United States
(12) Patent Application Publication
(10) Pub. No.: US 2019/0296207 A1
(43) Pub. Date: Sep. 26, 2019

(54) TACTILE DEVICE

(71) Applicant: ALPS ALPINE CO., LTD., Tokyo (JP)

(72) Inventors: Yuzuru KAWANA, Miyagi (JP); Kunio SATO, Miyagi (JP); Hajime SHIKATA, Miyagi (JP)

(21) Appl. No.: 16/435,766

(22) Filed: Jun. 10, 2019

Related U.S. Application Data
(63) Continuation of application No. PCT/JP2017/044708, filed on Dec. 13, 2017.

(30) Foreign Application Priority Data
Jan. 13, 2017 (JP) 2017-004647

(51) Int. Cl. H01L 35/32; H01L 35/30; G08B 6/00

(52) U.S. Cl. CPC H01L 35/32; H01L 35/08; G08B 6/00; H01L 35/30

(57) ABSTRACT

A tactile device includes a contact surface touchable by a tactile subject, a thermoelectric transducer which generates cold or warmth transferred to the contact surface, and a temperature sensor which detects the contact surface temperature. The thermoelectric transducer includes first and second heat transfer members, and a thermoelectric element which generates a temperature difference between the first and second heat transfer members based power supplied thereto. The contact surface is formed on a surface of the first heat transfer member, or on a surface of a third heat transfer member contacting the surface of the first heat transfer member. The temperature sensor is arranged on an outer side of a region where the contact surface is formed on the surface of the first heat transfer member, or on an outer side of a region contacting the third heat transfer member at the surface of the first heat transfer member.

### CROSS-REFERENCE TO RELATED APPLICATIONS

This application is a continuation application of International Application No. PCT/JP2017/044708 filed on Dec. 13, 2017 and designated the U.S., which is based upon and claims priority to Japanese Patent Application No. 2017-004647, filed on Jan. 13, 2017, the entire contents of which are incorporated herein by reference.

### BACKGROUND OF THE INVENTION

### 1. Field of the Invention

The present invention relates to a tactile device which presents tactile senses such as sense of warmth and sense of cold, and more particularly to a tactile device which uses a thermoelectric element.

The tactile device may sometimes also be referred to as a tactile presentation device, or a tactile sense presentation device, for example.

### 2. Description of the Related Art

Recently, devices that realize Virtual Reality (VR) have become popular, and techniques for electrically and/or mechanically reproducing human tactile senses are gathering attention. For example, Japanese Laid-Open Patent Publication No. H07-72018 describes a tactile device which uses a Peltier element to reproduce arbitrary sense of warmth.

In order to reproduce the arbitrary sense of warmth using the Peltier element, the temperature of the Peltier element needs to be detected and controlled. According to the device illustrated in FIG. 7 and FIG. 8 of Japanese Laid-Open Patent Publication No. H07-72018, a sensor for detecting the temperature is provided on a surface of the Peltier element that is touched by a finger or the like. However, when the sensor is adhered on a part of the Peltier element touched by the finger or the like, the sensor may easily come off or may easily wear due to friction or the like. For this reason, the durability of the tactile device that uses the Peltier element having the sensor provided thereon is poor. In addition, the provision of the sensor on the Peltier element forms a concavo-convex surface which gives a strange sense of touch.

### SUMMARY OF THE INVENTION

One object of the embodiments of the present invention is to provide a tactile device which can reduce durability deterioration, and present excellent tactile senses without giving strange senses.

According to one aspect of the embodiments, a tactile device includes a contact surface which is touchable by a tactile subject; a thermoelectric transducer configured to generate cold or warmth transferred to the contact surface; and a temperature sensor configured to detect a temperature of the contact surface, wherein the thermoelectric transducer includes a first heat transfer member, a second heat transfer member, and at least one thermoelectric element configured to generate a temperature difference between the first heat transfer member and the second heat transfer member based power supplied thereto, wherein the contact surface is formed on a first surface of the first heat transfer member, or on a surface of a third heat transfer member contacting the first surface of the first heat transfer member, and wherein the temperature sensor is arranged on an outer side of a region where the contact surface is formed on the first surface of the first heat transfer member, or on an outer side of a region contacting the third heat transfer member at the first surface of the first heat transfer member.

Other objects and further features of the present invention will be apparent from the following detailed description when read in conjunction with the accompanying drawings.

### BRIEF DESCRIPTION OF DRAWINGS

FIG. 1 is a perspective view illustrating an example of a tactile device according to a first embodiment;

FIG. 2 is a front view illustrating the example of the tactile device according to the first embodiment;

FIG. 3 is a plan view illustrating the example of the tactile device according to the first embodiment;

FIG. 4 is a diagram in which illustration of a first heat transfer member in the plan view of FIG. 3 is omitted;

FIG. 5 is a diagram illustrating an example of a configuration of a control system in the example of the tactile device according to the first embodiment;

FIG. 6 is a perspective view illustrating an example of the tactile device according to a second embodiment;

FIG. 7 is a front view illustrating the example of the tactile device according to the second embodiment; and

FIG. 8 is a plan view illustrating the example of the tactile device according to the second embodiment.

### DESCRIPTION OF THE PREFERRED EMBODIMENTS

In one embodiment, a tactile device includes a contact surface which is touchable by a tactile subject, a thermoelectric transducer configured to generate cold or warmth transferred to the contact surface, and a temperature sensor configured to detect a temperature of the contact surface. The thermoelectric transducer includes a first heat transfer member, a second heat transfer member, and a thermoelectric element configured to generate a temperature difference between the first heat transfer member and the second heat transfer member based power supplied thereto. The contact surface is formed on a first surface of the first heat transfer member, or on a surface of a third heat transfer member contacting the first surface of the first heat transfer member. The temperature sensor is arranged on an outer side of a region where the contact surface is formed on the first surface of the first heat transfer member, or on an outer side of a region contacting the third heat transfer member at the first surface of the first heat transfer member.

According to this configuration, because the temperature sensor is arranged on the outer side of the region where the contact surface is formed on the first surface of the first heat transfer member, the tactile subject such as the finger or the like does not directly touch the temperature sensor. For this reason, it is possible to improve the durability of the tactile device compared to a conventional device having the temperature sensor that is directly touched by the tactile subject such as the finger or the like. In addition, because a strange sense of touch that is generated when the tactile subject directly touches the temperature sensor will not occur, it is possible to present an excellent tactile sense.

In addition, according this configuration, the temperature sensor is arranged on the outer side of a region where the third heat transfer member contacts the first surface of the first heat transfer member. Hence, compared to a case where the temperature sensor is arranged within the above described region, an adhesion between the first heat transfer member and the third heat transfer member is improved, and the cold or the warmth of the thermoelectric element is more easily transferred to the contact surface via the third heat transfer member.

Preferably, the first heat transfer member may have a plate shape. The thermoelectric element may contact a second surface of the first heat transfer member opposite to the first surface of the first heat transfer member. The temperature sensor may be arranged on the second surface of the first heat transfer member.

According to this configuration, because the temperature sensor is arranged on the second surface of the first heat transfer member, not formed with the contact surface, the tactile subject such as the finger or the like does not directly touch the temperature sensor. For this reason, it is possible to improve the durability of the tactile device compared to the conventional device, and the generation of the strange sense of touch can be prevented to present an excellent tactile sense.

In addition, according to this configuration, the first surface of the first heat transfer member having the plate shape contacts the surface of the third heat transfer member having the plate shape. For this reason, the first heat transfer member and the third heat transfer member can easily make contact in a large area, and the cold or the warmth of the thermoelectric element can easily be transferred to the contact surface.

Preferably the tactile device further includes a heat sink member configured to reduce a temperature change of the second heat transfer member. The second heat transfer member may have a plate shape. The first heat transfer member and the second heat transfer member may be arranged to oppose each other. The thermoelectric element may contacts a first surface of the second heat transfer member. The heat sink member may contact a second surface of the second heat transfer member opposite to the first surface of the second heat transfer member. Two detection terminal parts configured to couple to two detection wirings which transmit a detection signal of the temperature sensor may be formed on the first surface of the second heat transfer member.

According to this configuration, the heat sink member contacts the second surface of the second heat transfer member, and the two detection terminal parts are formed on the first surface of the second heat transfer member. For this reason, the second heat transfer member and the heat sink member can make contact in a large area, without interference from the two detection terminal parts.

Preferably, the temperature sensor is positioned between the two detection terminal parts in a plan view viewed in a direction perpendicular to each of the first and second surface of the first heat transfer member and the second heat transfer member.

According to this configuration, a region occupied by the two detection terminal parts and the temperature sensor in the plan view is small, and an occupied region where the thermoelectric element is arranged becomes large relative to the occupied region.

Preferably, the first heat transfer member and the second heat transfer member may have a rectangular shape in the plan view. The two detection terminal parts may be arranged at an end part of the second heat transfer member along one side of the rectangular shape.

According to this configuration, the detection terminal parts are arranged at the end part of the second heat transfer member, along the one side of the rectangular shape of the first surface of the second heat transfer member. Hence, the region where the thermoelectric element is arranged becomes large relative to the region occupied by the two detection terminal parts.

Preferably, two driving terminal parts configured to coupled to two driving wirings which supply power to the thermoelectric element may be formed on the first surface of the second heat transfer member. The two driving terminal parts and the two detection terminal parts may be arranged at the end part of the second heat transfer member along the one side of the rectangular shape.

According to this configuration, the heat sink member contacts the second surface of the second heat transfer member, and the two driving terminal parts are formed on the first surface of the second heat transfer member. For this reason, the second heat transfer member and the heat sink member can make contact in a large area, without interference from the two driving terminal parts. In addition, the two driving terminal parts, together with the two detection terminal parts, are arranged at the end part of the first surface of the second heat transfer member, along the one side of the rectangular shape of the first surface of the second heat transfer member. Hence, the region where the thermoelectric element is arranged becomes large relative to the region occupied by the four terminal parts.

### First Embodiment

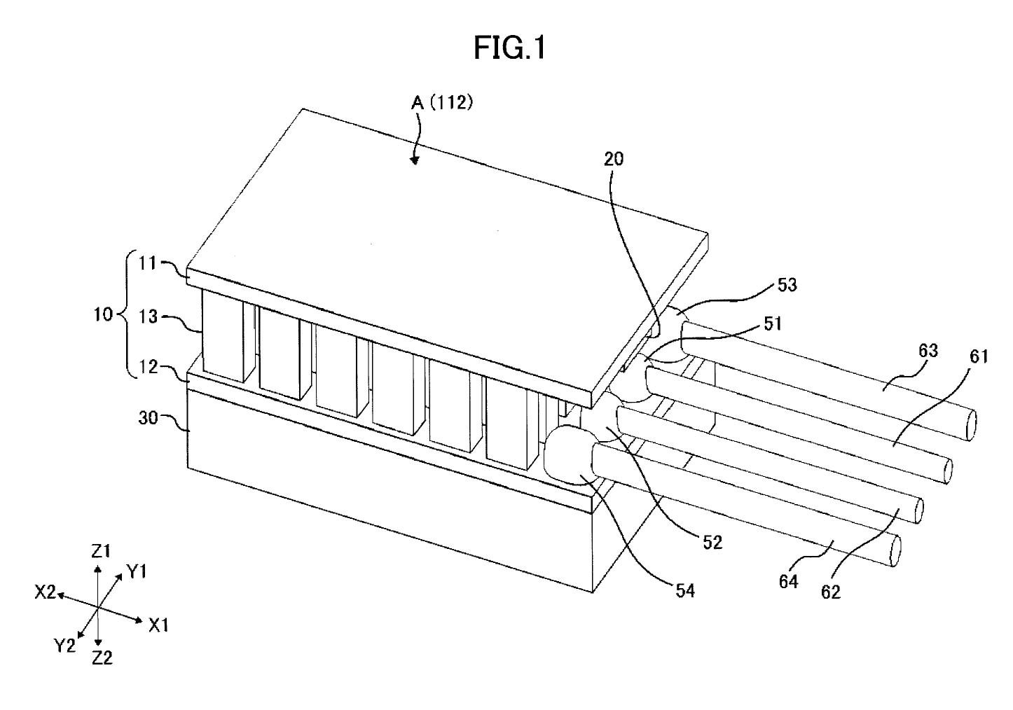

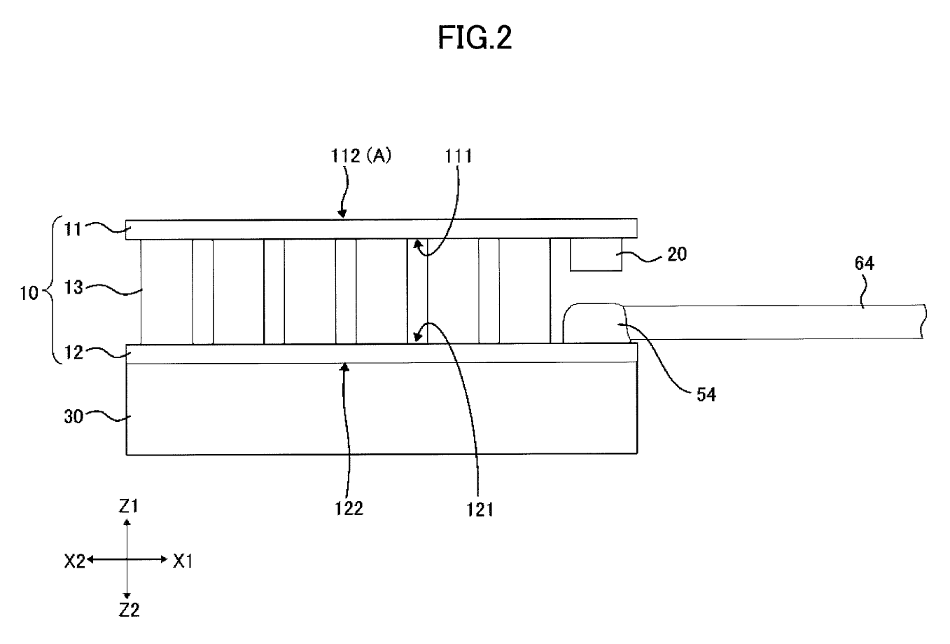

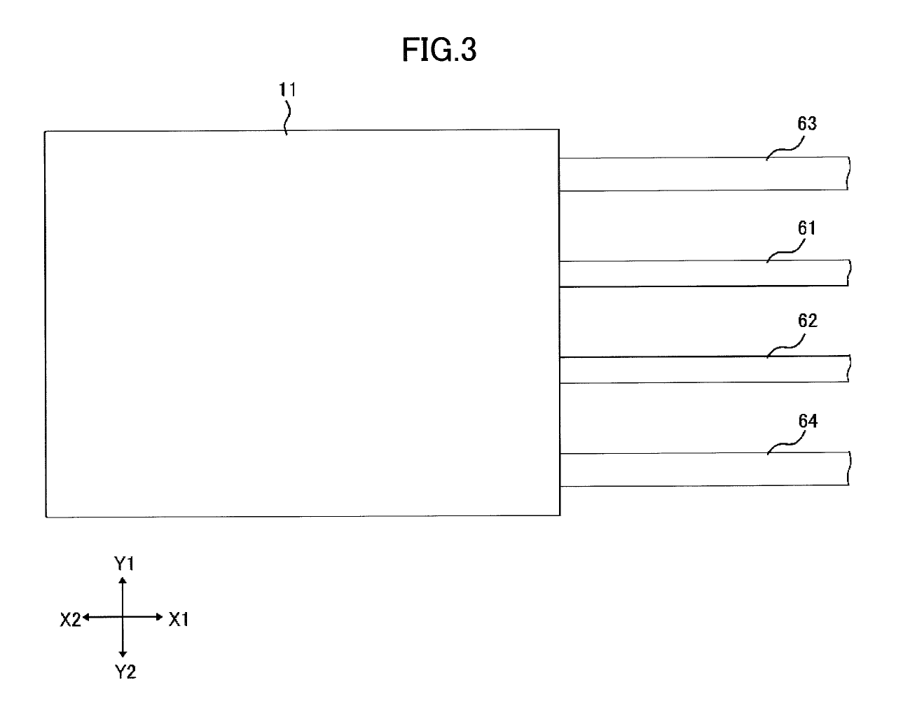

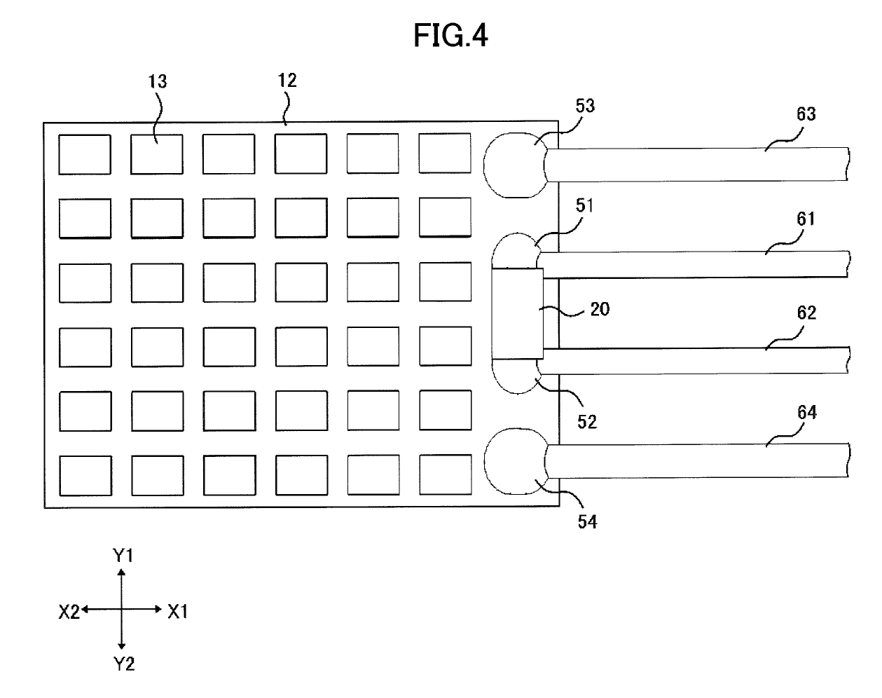

A tactile device according to a first embodiment of the present invention will be described by referring to the drawings. FIG. 1 is a perspective view illustrating an example of the tactile device according to a first embodiment. FIG. 2 is a front view illustrating the example of the tactile device according to the first embodiment. FIG. 3 is a plan view illustrating the example of the tactile device according to the first embodiment. FIG. 4 is a diagram in which illustration of a first heat transfer member 11 in the plan view of FIG. 3 is omitted.

In this specification, “X”, “Y”, and “Z” denote three directions that are perpendicular to each other. In addition, mutually opposite directions of the X-direction are denoted by “X1” and “X2”, mutually opposite directions of the Y-direction are denoted by “Y1” and “Y2”, and mutually opposite directions of the Z-direction are denoted by “Z1” and “Z2”. The front view of FIG. 2 is a view from the Y2-side viewed in the Y1-direction, and the plan view of FIG. 3 is a view from the Z1-side viewed in the Z2-direction. In the following description, viewing in the Z-direction may also be referred to as “in a plan view”.

The tactile device according to this embodiment includes a contact surface A which is touchable by a tactile subject such as a finger or the like. In the example illustrated in FIG. 1, the contact surface A is a plan perpendicular to the Z-direction, and is formed on a surface of a thermoelectric transducer 10 which will be described later.

As illustrated in FIG. 1 and FIG. 2, the tactile device according to this embodiment includes the thermoelectric transducer 10, a temperature sensor 20, and a heat sink member 30.

The thermoelectric transducer 10 generates cold or warmth transferred to the contact surface A. In the example illustrated in FIG. 1 and FIG. 2, the thermoelectric transducer 10 includes the first heat transfer member 11, a second heat transfer member 12, and a plurality of thermoelectric elements 13.

The first heat transfer member 11 and the second heat transfer member 12 respectively have a plate shape, and are arranged to oppose each other. Top and bottom surface of each of the first heat transfer member 11 and the second heat transfer member 12 in FIG. 2 respectively are approximately parallel to the Z-direction. In other words, a surface 111 on the Z2-side and a surface 112 of the Z1-side of the first heat transfer member 11 are both approximately perpendicular to the Z-direction. In addition, a surface 121 on the Z1-side and a surface 122 on the Z2-side of the second heat transfer member 12 are both approximately perpendicular to the Z-direction. The contact surface A is formed on the surface 112 on the Z1-side of the first heat transfer member 11. In the plan view, the first heat transfer member 11 and the second heat transfer member 12 respectively have a rectangular shape. As illustrated in FIG. 3, the rectangular shapes of the first heat transfer member 11 and the second heat transfer member 12 are approximately congruent, and overlap approximately in their entirety in the plan view. The first heat transfer member 11 and the second heat transfer member 12 may be made of an insulating material, such as ceramics, resins, or the like, for example.

The thermoelectric elements 13 may be Peltier elements, for example. The thermoelectric elements 13 generate a temperature difference between the first heat transfer member 11 and the second heat transfer member 12 based on power supplied from a thermoelectric element driving circuit 80 which will be described later.

As illustrated in FIG. 1, the thermoelectric elements 13 have a rectangular column shape extending in the Z-direction. One end surface of each thermoelectric element 13 on the Z1-side contacts the surface 111 on the Z2-side of the first heat transfer member 11. The other end surface of each thermoelectric element 13 on the Z2-side contacts the surface 121 on the Z1-side of the second heat transfer member 12. As illustrated in FIG. 4, the plurality of thermoelectric elements 13 are arranged in a matrix arrangement in the plan view. In the example illustrated in FIG. 4, the number of columns arranged in the X-direction, and the number of rows arranged in the Y-direction in the matrix arrangement respectively are six.

The temperature sensor 20 detects the temperature of the contact surface A. The temperature sensor 20 may include a thermistor, for example. The temperature sensor 20 is arranged on an outer side of a region where the contact surface A is formed on the surface of the first heat transfer member 11. For example, the temperature sensor 20 is arranged on the surface 111 on the Z2-side of the first heat transfer member 11, as illustrated in FIG. 1 and FIG. 2.

The heat sink member 30 is arranged to contact the surface 122 on the Z2-side of the second heat transfer member 12, and reduces a temperature change of the second heat transfer member 12. The heat sink member 30 may be a component having a metal housing which has a high thermal conductivity, for example. More particularly, the heat sink member 30 may be a component including a vibration generator, such as a solenoid, a motor, or the like, for example.

As illustrated in FIG. 1 and FIG. 4, the tactile device according to this embodiment includes two detection terminal parts 51 and 52. The detection terminal parts 51 and 52 are respectively connected to two detection wirings 61 and 62 for transmitting a detection signal of the temperature sensor 20. A current supplied to a sensor element such as a thermistor or the like included in the temperature sensor 20, flows through the two detection wirings 61 and 62. The detection terminal parts 51 and 52 are land electrodes, for example, and are respectively connected to the detection wirings 61 and 62 by solder.

The two detection terminal parts 51 and 52 are formed on the surface 121 on the Z1-side of the second heat transfer member 12. The detection terminal parts 51 and 52 are arranged at an end part on the X1-side of the second heat transfer member 12, along one side on the X1-side of the rectangular shape of the surface 121 of the second heat transfer member 12 (that is, along the Y-direction). As illustrated in FIG. 4, the temperature sensor 20 is positioned between the detection terminal parts 51 and 52 in the plan view. In addition, the temperature sensor 20 is positioned at an approximate center along the Y-direction of the second heat transfer member 12 in the plan view.

As illustrated in FIG. 1 and FIG. 4, the tactile device according to this embodiment includes two driving terminal parts 53 and 54. The driving terminal parts 53 and 54 are respectively connected to two driving wirings 63 and 64 for supplying power to the thermoelectric elements 13. The plurality of thermoelectric elements 13 of the thermoelectric transducer 10 are connected in series by wirings formed on the first heat transfer member 11 and the second heat transfer member 12. A current supplied to the plurality of thermoelectric elements 13 that are connected in series flows through the two driving wirings 63 and 64. The driving terminal parts 53 and 64 are land electrodes, for example, and are respectively connected to the driving wirings 63 and 64 by solder.

The two driving terminal parts 53 and 54 are formed on the surface 121 on the Z1-side of the second heat transfer member 12. The driving terminal parts 53 and 54 are arranged at the end part on the X1-side of the second heat transfer member 12, along the one side on the X1-side of the rectangular shape of the surface 121 of the second heat transfer member 12 (that is, along the Y-direction). As illustrated in FIG. 4, the two driving terminal parts 53 and 54 are arranged at positions sandwiching the two detection terminal parts 51 and 52 along the Y-direction.

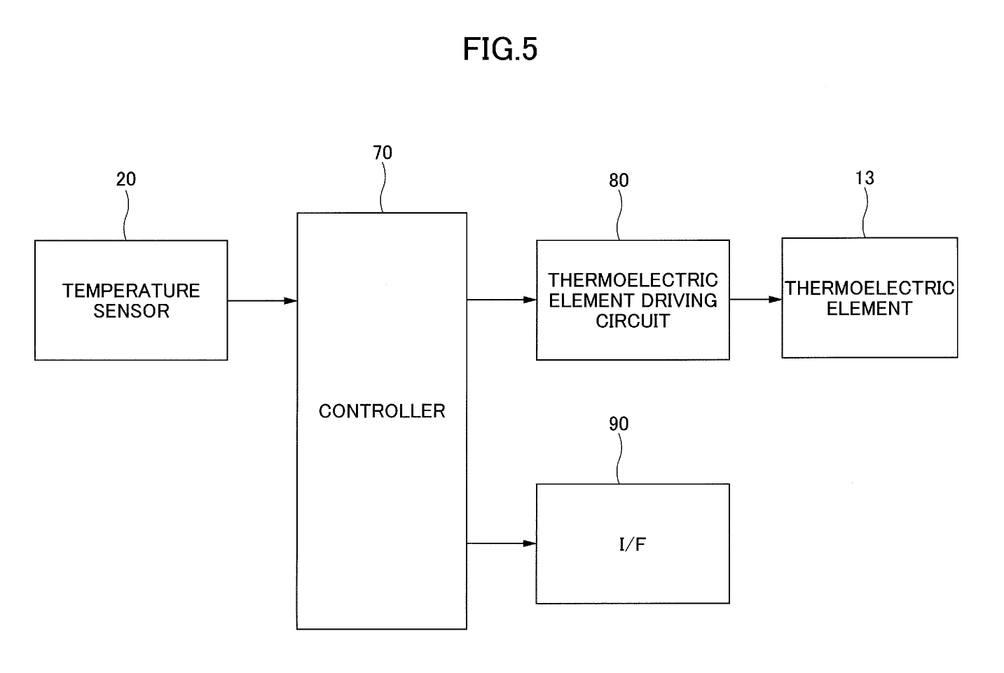

FIG. 5 is a diagram illustrating an example of a configuration of a control system in the example of the tactile device according to the first embodiment. As illustrated in FIG. 5, the tactile device according to this embodiment includes a controller 70 which controls the general operation of the tactile device, a thermoelectric element driving circuit 80 which supplies power to each of the thermoelectric elements 13 according to control of the controller 70, and an interface part 90 which exchanges signals of control commands, temperature detection values, or the like between a device (host controller or the like) which is not illustrated and the controller 70.

The controller 70 performs a process to control the temperature of the contact surface A, according to the control command input via the interface part 90. In other words, the controller 70 controls the power supplied from the thermoelectric element driving circuit 80 to the thermoelectric elements 13 (for example, a magnitude of the current supplied to the thermoelectric elements 13), so that the temperature of the contact surface A detected by the temperature sensor 20 approaches a temperature specified by the control command. In addition, the controller 70 performs a process to control the temperature of the contact surface A, so that the temperature of the contact surface A is maintained within a predetermined range in a steady state (a state where the finger or the like does not touch the contact surface A) before and after a period of time (or duration) in which the tactile sense is presented to the tactile subject. Hence, a response speed of presenting the tactile sense can be increased.

The tactile device according to the first embodiment having the above described configuration can obtain the following advantageous features.

(1-1) In the tactile device according to this embodiment, because the temperature sensor 20 is arranged on the outer side of the region where the contact surface A is formed on the surface of the first heat transfer member 11, the tactile subject such as the finger or the like does not directly touch the temperature sensor 20. For this reason, it is possible to improve the durability of the tactile device compared to a conventional device having the temperature sensor that is directly touched by the tactile subject such as the finger or the like. In addition, because a strange sense of touch that is generated when the tactile subject directly touches the temperature sensor 20 will not occur, it is possible to present an excellent tactile sense.

(1-2) In the tactile device according to this embodiment, because the temperature sensor 20 is arranged on the surface 111 on the Z2-side of the first heat transfer member, not formed with the contact surface A, the tactile subject such as the finger or the like does not directly touch the temperature sensor 20. For this reason, it is possible to improve the durability of the tactile device compared to the conventional device, and the generation of the strange sense of touch can be prevented to present an excellent tactile sense. In addition, because the temperature sensor 20 is arranged between the first heat transfer member 11 and the second heat transfer member 12, it is possible to reduce the size of the tactile device along the Z-direction.

(1-3) In the tactile device according to this embodiment, the heat sink member 30 contacts the surface 122 on the Z2-side of the second heat transfer member 12, and the two detection terminal parts 51 and 52 are formed on the surface 121 on the Z1-side of the second heat transfer member 12. For this reason, the second heat transfer member 12 and the heat sink member 30 can make contact in a large area, without interference from the two detection terminal parts 51 and 52, and the temperature change of the second heat transfer member 12 can be effectively reduced. By reducing the temperature change of the second heat transfer member 12, a setting accuracy of the temperature of the contact area A improves, and a high-quality tactile sense can be presented.

(1-4) In the tactile device according to this embodiment, the temperature sensor 20 is positioned between the two detection terminal parts 51 and 52, in the plan view viewed in the Z-direction perpendicular to each surface of the first transfer member 11 and the second heat transfer member 12. Hence, an occupied region occupied by the two detection terminal parts 51 and 52 and the temperature sensor 20 in the plan view is small, and a region where the thermoelectric elements 13 are arranged becomes large relative to the occupied region. Accordingly, it is possible to increase the density with which the thermoelectric elements 13 are arranged, and reduce the size of the tactile device.

(1-5) In the tactile device according to this embodiment, the detection terminal parts 51 and 52 are arranged at the end part of the second heat transfer member 12, along the one side of the rectangular shape of the surface 121 of the second heat transfer member 12. In other words, the two detection terminal parts 51 and 52 are collectively arranged at the end part of the surface 121. Hence, the region where the thermoelectric elements 13 are arranged becomes large relative to the region occupied by the two detection terminal parts 51 and 52. As a result, it is possible to increase the density with which the thermoelectric elements 13 are arranged, and reduce the size of the tactile device.

(1-6) In the tactile device according to this embodiment, the heat sink member 30 contacts the surface 122 on the Z2-side of the second heat transfer member 12, and the two driving terminal parts 53 and 54 are formed on the surface 121 on the Z1-side of the second heat transfer member 12. For this reason, the second heat transfer member 12 and the heat sink member 30 can make contact in a large area, without interference from the two driving terminal parts 53 and 54, and the temperature change of the second heat transfer member 12 can be effectively reduced.

(1-7) In the tactile device according to this embodiment, the two driving terminal parts 53 and 54, together with the two detection terminal parts 51 and 52, are arranged at the end part of the surface 121 of the second heat transfer member 12, along the one side of the rectangular shape of the surface 121 of the second heat transfer member 12. In other words, the four terminal parts (51 through 54) are collectively arranged at the end part of the surface 121. Hence, the region where the thermoelectric elements 131 are arranged becomes large relative to the region occupied by the four terminal parts. As a result, it is possible to increase the density with which the thermoelectric elements 13 are arranged, and reduce the size of the tactile device.

### Second Embodiment

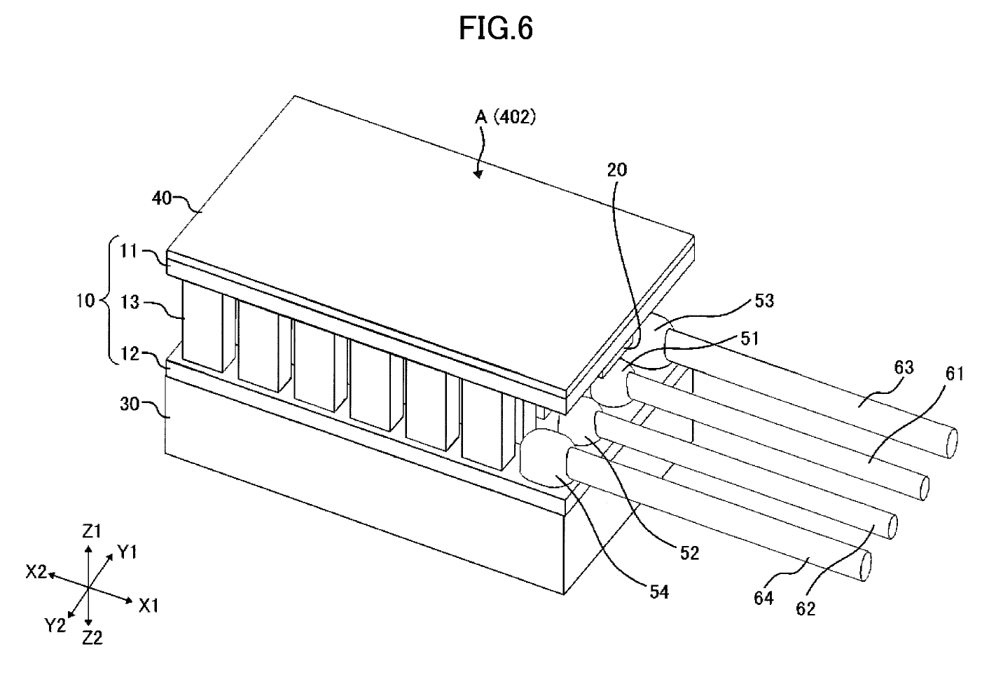

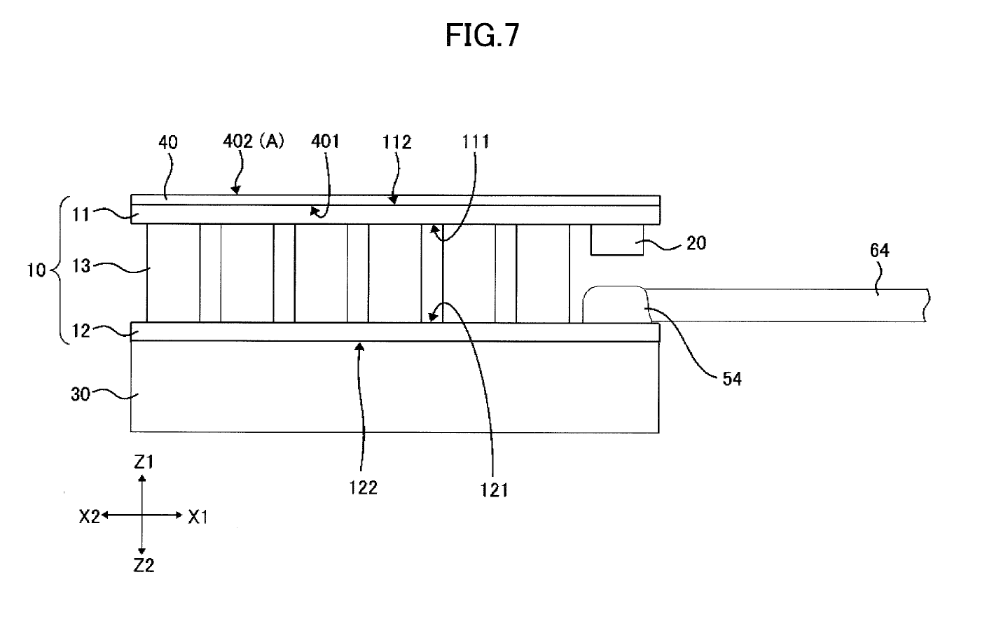

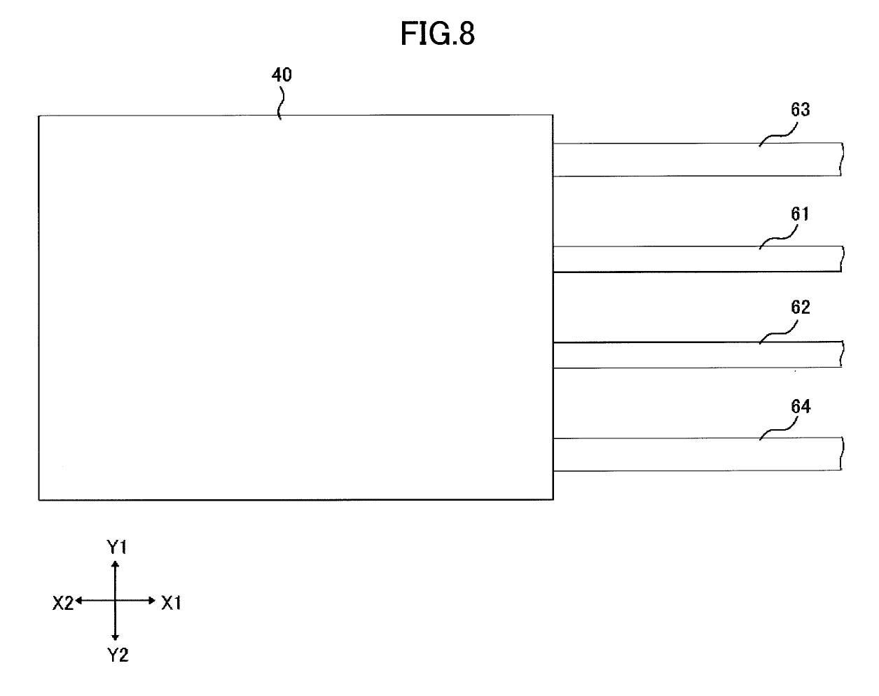

Next, a second embodiment of the present invention will be described. FIG. 6, FIG. 7, and FIG. 8 are diagram illustrating an example of the tactile device according to the second embodiment. FIG. 6 is a perspective view, FIG. 7 is a front view, and FIG. 8 is a plan view respectively illustrating the example of the tactile device according to the second embodiment.

The tactile device according to the second embodiment is similar to the tactile device according to the first embodiment described above, however, the tactile device according to the second embodiment is additionally provided with a third heat transfer member 40. Otherwise, the configuration of the tactile device according to the present invention is basically the same as that of the tactile device according to the first embodiment. The third heat transfer member 40 is an example of another heat transfer member of the present invention. In the following, the differences of the tactile device according to the second embodiment from the tactile device according to the first embodiment will be described.

The third heat transfer member 40 contacts the surface 112 on the Z1-side of the first heat transfer member 11, and has a plate shape as illustrated in FIG. 6 and FIG. 7. The contact surface A is formed on a surface 402 on the Z1-side of the third heat transfer member 40. A surface 401 on the Z2-side of the third heat transfer member 40 contacts the surface 112 on the Z1-side of the first heat transfer member 11. The third heat transfer member 40 may be a component such as a flexible printed circuit, a protection sheet member, a casing or a housing for accommodating the tactile device, or the like. The cold and the warmth from the first heat transfer member 11 is transferred to the contact surface A, indirectly via the third heat transfer member 40.

The tactile device according to the second embodiment having the above described configuration can obtain the following advantageous features, in addition to the advantageous features obtainable by the tactile device according to the first embodiment.

(2-1) In the tactile device according to the second embodiment, the temperature sensor 20 is arranged on the outer side of a region where the third heat transfer member 40 contacts the surface of the first heat transfer member 11. Hence, compared to a case where the temperature sensor 20 is arranged within the above described region, an adhesion between the first heat transfer member 11 and the third heat transfer member 40 is improved, and the cold or the warmth of the thermoelectric elements 13 is more easily transferred to the contact surface A via the third heat transfer member 40. Accordingly, the setting accuracy of the temperature of the contact area A improves, and a high-quality tactile sense can be presented.

(2-2) In the tactile device according to the second embodiment, the surface 112 on the Z1-side of the first heat transfer member 11 having the plate shape contacts the surface 401 on the Z2-side of the third heat transfer member 40 having the plate shape. For this reason, the first heat transfer member 11 and the third heat transfer member 40 can easily make contact in a large area, and the cold or the warmth of the thermoelectric elements 13 can easily be transferred to the contact surface A. Accordingly, the setting accuracy of the temperature of the contact area A improves, and a high-quality tactile sense can be presented.

Although the present invention is described above by way of embodiments, the present invention is not limited to the embodiments described above. In other words, it is apparent to those skilled in the art that various variations, combinations, sub-combinations, and substitutions may be made to the structures of the embodiments described above without departing from the scope of the present invention.

In the embodiments described above, the temperature sensor 20 is arranged on the surface 111 on the Z2-side of the first heat transfer member 11, however, the present invention is not limited to such an arrangement. For example, in a case where a range of the contact surface A is limited to a portion of the surface 112 on the Z1-side of the first heat transfer member 11 (a case where the contact surface A is limited by a resin casing or the like), the temperature sensor 20 may be arranged on the surface 112 on the Z1-side of the first heat transfer member 11, in a region on the outer side of the contact surface A. In this case, it is also possible to prevent the tactile subject such as the finger or the like from directly touching the temperature sensor 20. For this reason, it is possible to improve the durability of the tactile device compared to the conventional device, and the generation of the strange sense of touch can be prevented to present an excellent tactile sense.

In the embodiments described above, the temperature sensor 20 is arranged at the end part of the surface 111 on the Z2-side of the first heat transfer member 11. However, in another embodiment of the present invention, the temperature sensor may be arranged at a location separated from the end part (for example, a center part) of the surface 111.

The shape and size of each member, the positional relationship of the members, the number of members, or the like in each of the embodiments described above are examples, and the present invention is not limited to these examples.

Accordingly, the embodiments of the present invention can provide a tactile device which can reduce durability deterioration, and present excellent tactile senses without giving strange senses.

Although the embodiments are numbered with, for example, “first,” or “second,” the ordinal numbers do not imply priorities of the embodiments.

What is claimed is:

1. A tactile device comprising:
a contact surface which is touchable by a tactile subject;
a thermoelectric transducer configured to generate cold or warmth transferred to the contact surface; and
a temperature sensor configured to detect a temperature of the contact surface,
wherein the thermoelectric transducer includes
a first heat transfer member,
a second heat transfer member, and
at least one thermoelectric element configured to generate a temperature difference between the first heat transfer member and the second heat transfer member based power supplied thereto,
wherein the contact surface is formed on a first surface of the first heat transfer member, or on a surface of a third heat transfer member contacting the first surface of the first heat transfer member, and
wherein the temperature sensor is arranged on an outer side of a region where the contact surface is formed on the first surface of the first heat transfer member, or on an outer side of a region contacting the third heat transfer member at the first surface of the first heat transfer member.

2. The tactile device as claimed in claim 1, wherein
the first heat transfer member has a plate shape,
the at least one thermoelectric element contacts a second surface of the first heat transfer member opposite to the first surface of the first heat transfer member, and
the temperature sensor is arranged on the second surface of the first heat transfer member.

3. The tactile device as claimed in claim 2, further comprising:
a heat sink member configured to reduce a temperature change of the second heat transfer member,
wherein the second heat transfer member has a plate shape,
wherein the first heat transfer member and the second heat transfer member are arranged to oppose each other,
wherein the at least one thermoelectric element contacts a first surface of the second heat transfer member,
wherein the heat sink member contacts a second surface of the second heat transfer member opposite to the first surface of the second heat transfer member, and
wherein two detection terminal parts configured to couple to two detection wirings which transmit a detection signal of the temperature sensor are formed on the first surface of the second heat transfer member.

4. The tactile device as claimed in claim 3, wherein the temperature sensor is positioned between the two detection terminal parts in a plan view viewed in a direction perpendicular to each of the first and second surface of the first heat transfer member and the second heat transfer member.

5. The tactile device as claimed in claim 4, wherein
the first heat transfer member and the second heat transfer member have a rectangular shape in the plan view, and
the two detection terminal parts are arranged at an end part of the second heat transfer member along one side of the rectangular shape.

6. The tactile device as claimed in claim 5, wherein
two driving terminal parts configured to coupled to two driving wirings which supply power to the at least one thermoelectric element are formed on the first surface of the second heat transfer member, and
the two driving terminal parts and the two detection terminal parts are arranged at the end part of the second heat transfer member along the one side of the rectangular shape.
